(19) United States
(12) Patent Application Publication
(10) Pub. No.: US 2026/0367296 A1
(43) Pub. Date: Nov. 19, 2026

(54) META-OPTICAL ELEMENTS ON A CURVED SURFACE

(71) Applicant: NIL Technology ApS, Kongens Lyngby (DK)

(72) Inventor: Maksim Zalkovskij, Copenhagen (DK)

(21) Appl. No.: 19/487,081

(22) PCT Filed: May 29, 2024
(86) PCT No.: PCT/EP2024/064843

§ 371 Date: Nov. 24, 2025

Related U.S. Application Data
(60) Provisional application No. 63/504,871, filed on May 30, 2023.

(51) Int. Cl. G02B 5/18; G03F 7/00; G03F 7/42

(52) U.S. Cl. CPC G02B 5/1852; G03F 7/0002; G03F 7/0005; G03F 7/42

(57) ABSTRACT

A method includes, providing a substrate comprising a curved surface, forming a resist layer on the curved surface, patterning the resist layer on the curved surface using imprint lithography to provide a patterned resist layer, removing residual resist material from the patterned resist layer, forming, by atomic layer deposition, a first layer on the patterned resist layer, and removing the patterned resist layer to form a patterned first layer on the curved surface.

### TECHNICAL FIELD

The present disclosure relates to optical devices that include one or more metastructures.

### BACKGROUND

A metasurface refers to a surface with distributed small structures (e.g., meta-atoms) arranged to interact with light in a particular manner. For example, a metasurface can be a surface with a distributed array of nanostructures. The nanostructures may, individually or collectively, interact with light waves. For example, the nanostructures or other meta-atoms may change a local amplitude, a local phase, or both, of an incoming light wave.

### SUMMARY

In one aspect, the present disclosure describes a method that includes, providing a substrate comprising a curved surface, forming a resist layer on the curved surface, patterning the resist layer on the curved surface using imprint lithography to provide a patterned resist layer, removing residual resist material from the patterned resist layer, forming, by atomic layer deposition, a first layer on the patterned resist layer, and removing the patterned resist layer to form a patterned first layer on the curved surface.

Implementations of the method may include one or more of the following. The patterned first layer on the curved surface includes a metastructure. The metastructure includes one or more structures, formed perpendicular to the curved surface, and a height of each of the one or more metastructures is formed to be normal to the curved surface. Each of the one or more structures formed perpendicular to the curved surface have a diameter of 30-500 nanometers. The method includes, encapsulating the patterned first layer in an encapsulation material.

Implementations of the method may include one or more of the following. The encapsulation material comprises spin-on glass or polymer. The method includes removing a portion of the first layer so as to expose at least part of the patterned resist layer. Removing the portion of the first layer so as to expose at least a part of the patterned resist layer includes performing an etch of the first layer. The substrate is a substrate that is transparent to visible light, infrared, near-infrared, or short-wave infrared. Patterning the resist layer includes physically contacting a mold to the resist layer, where the mold includes a pattern, pressing the mold and the substrate together, curing the resist, and separating the mold from the resist layer to form the patterned resist layer.

Implementations of the method may include one or more of the following. The mold includes a flexible material. The curved surface includes a convex surface with respect to the substrate. The curved surface includes a concave surface with respect to the substrate. The curved surface includes a combination of multiple convex surfaces with respect to the substrate. The curved surface includes a combination of multiple concave surfaces with respect to the substrate. The curved surface includes a concave surface with respect to the substrate and a convex surface with respect to the substrate. The resist is a thermally curable or UV-curable resist. Removing the residual resist material comprises using a dry etching technique. The first layer includes amorphous silicon, niobium oxide, titanium oxide, aluminum oxide, hafnium oxide, silicon oxide, strontium titanate oxide, tantalum oxide, gadolinium oxide, zirconium oxide, gallium oxide, or vanadium oxide.

In one aspect, the present disclosure describes a device including a substrate including a curved surface and one or more metastructures on the curved surface. The device may include one or more metastructures on the curved surface each with a diameter of up to 1000 nanometers. The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

FIG. 1 shows an example of a patterned resist on a curved surface formed using lithography.

FIGS. 2A-2I illustrate a method of fabricating a device.

FIG. 3A-3C show examples of substrates with curved surfaces.

FIGS. 4A-4K illustrate a method of fabricating a device.

Like reference symbols in the various drawings indicate like elements.

### DETAILED DESCRIPTION

A metasurface includes a surface with meta-atoms (in some cases, also referred to as nanostructures) that are arranged to interact with light in a particular manner. For example, a metasurface, which may be referred to as a metastructure, can be a surface with a distributed array of nanostructures. The nanostructures may, individually or collectively, interact with light waves. For example, the nanostructures or other meta-atoms may change a local amplitude, a local phase, or both, of an incoming light wave. In some instances, metasurfaces may perform optical functions that are traditionally performed by refractive and/or diffractive optical elements. The meta-atoms may be arranged, in some cases, in a pattern so that the metasurface functions as an optical element such as, for example, a lens, lens array, beam splitter, grating, grating coupler, fanout grating, diffuser, or other optical element. In other instances, the meta-atoms need not be arranged in a pattern. In some implementations, the metasurfaces may perform other functions, including polarization control, negative refractive index transmission, beam deflection, vortex generation, polarization conversion, optical filtering, and plasmonic optical functions.

The meta-atoms may be sub-wavelength nanostructures, which indicates that the structures have lateral dimensions, parallel to the substrate surface, that are less than a wavelength of light that is to be incident on to the structures. For example, in some instances, the nanostructures can be in the form of nanoscale features having dimensions less than 1 micron. Optical devices with different properties can be formed by adjusting the geometry of the meta-atoms/unit cell elements formed on a meta structure.

The present disclosure describes techniques that facilitate the formation of metastructures on a curved surface. Lithographic techniques such as maskless lithography, ultraviolet lithography, deep ultraviolet lithography, and electron beam lithography, among others may have one or more drawbacks when used to form structures on a curved surface. For instance, structures formed by such techniques may result in poor contact between a hard lithography mask or reticle and the substrate's curved surface, or in some instances, the curved surface may disturb the focal point. In some cases, the resolution achievable with those techniques is limited and/or the structures that are produced do not align perpendicular to the substrate surface. As a result of these and/or other drawbacks, the devices formed using such lithographic processes may exhibit poor performance. The techniques described herein cover processes for forming metastructures on curved surfaces that can, in some cases, provide the metastructures with improved contact, surface conformity, resolution, and/or focus, among other potential advantages. As described in more detail below, the metastructures may be formed to be perpendicular to the curved surface, that is the height of each structure extends in a direction that is parallel to the normal of the curved surface. In some cases, the metastructures may be formed to have a diameter of 30-500 nanometers. In other cases, the metastructures may be formed to have a diameter of up to 1000 nanometers.

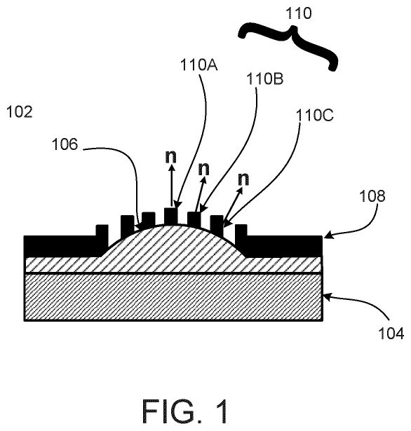

FIG. 1 shows an example of a patterned resist on a curved surface formed using lithography. As illustrated in FIG. 1, a substrate 102 has a curved surface 106. The substrate 102 may be comprised of a support substrate 104 in which the curved surface 106 is formed. The curved surface 106 may correspond to, e.g., a lens, such as a micro lens. The micro lens may be part of a micro lens array. In some implementations, the curved surface 106 may correspond to a collimator lens, an imaging lens, a focusing lens, a beam shaper. In other implementations, the curved surface 106 may correspond to an aspherical lens or an asymmetrical lens, for example, a lenticular lens. A resist layer 108 in which structures 110 are patterned is provided on the curved surface 106. Although the curved surface 106 is shown as convex relative to the substrate 102, the curved surface may be concave relative to substrate 102 or may include both convex and concave features. As explained above, lithography techniques, such as maskless lithography, ultraviolet lithography, deep ultraviolet lithography, and electron beam lithography may exhibit limitations when being used to pattern small structures on a curved surface. For example, as shown in FIG. 1, each of the one or more structures 110 formed in the patterned resist 108 do not align perpendicular to the curved surface 106. In more detail, as shown in FIG. 1, structure 110A is shaped as a rectangular column, the height of the column extending along a direction which is normal to the curved surface 106. On the other hand, structures 110B and 110C each have a height that is not aligned with the direction which is normal to the curved surface 106. When performing a later etching or deposition step with the resist 108 as a mask, a desired pattern may not faithfully transfer to the underlying substrate. In the case of optical elements, this limitation may lead to formation of devices that exhibit undesired properties such as poor resolution, poor focus, poor efficiency, or excessive straylight, among others.

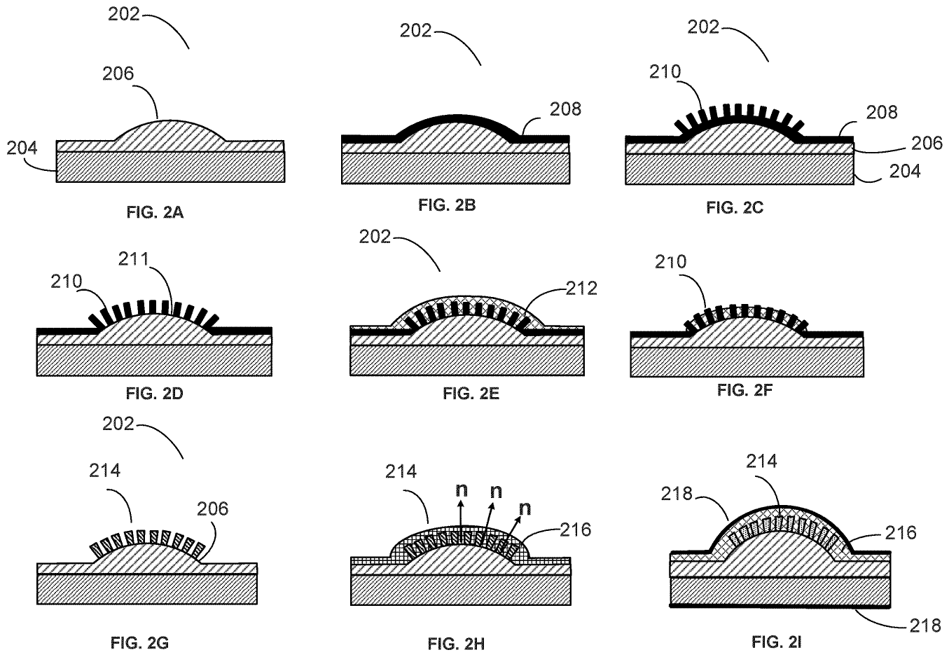

FIGS. 2A-2I illustrate manufacturing steps for forming a device that includes one or more metastructures formed on a curved surface. As illustrated in FIG. 2A, a substrate 202 having a curved surface 206 is provided. In some implementations, the curved surface 206 is formed in substrate 202. In these implementations, the curved surface 206 and the substrate are formed of the same material. Alternatively, the substrate 202 may include a support substrate 204 in which the curved surface 206 is formed. In these implementations, the support substrate 204 and the curved surface 206 may be formed of different materials. For example, the support substrate 204 may be formed of silicon, germanium, gallium arsenide, borofloat glass, fused silica, borosilicate glass, or any other suitable material. The curved surface 206 may be formed of a UV curable polymer or a thermal plastic. As explained herein, the curved surface 206 may include a convex surface, a concave surface, or a combination of convex and concave surfaces. The curved surface 206 may be formed by nanoimprint lithography (NIL) using, e.g., a mold. Substrates 202/204 may be selected to be optically transmissive with respect to a particular wavelength or range of wavelengths of radiation (e.g., infra-red (IR), near-infrared (NIR), short-wave infrared (SWIR) or visible light) depending on the application(s) in which the meta optical structures formed on the surface are to be used. For instance, the substrate 202 and/or support substrate 204 may be formed of borosilicate glass or fused silica, although other materials may be used. In some cases, the substrate 202 may include material that is reflective to incident light such as a metal or other mirrored surface.

Next, as shown in FIG. 2B, at least one resist layer 208 is formed on the curved surface 206 of the substrate 202. In some implementations, one or more resist layers may be formed on the curved surface 206. In some cases, the at least one resist layer 208 includes a nanoimprint resist that is a UV-curable resist. In other examples, the at least one resist layer 208 includes a thermally curable resist. In some implementations, the resist layer 208 is a high index resist including, but not limited to, polymethacrylate, polyurethane, or polycarbonate. The resist layer 208 may be applied by different deposition techniques. For example, in some cases, the resist layer 208 is applied by spin-on processes, spray coating processes, or injection dispensing processes.

As shown in FIG. 2C, the resist layer 208 on the curved surface 206 is patterned using imprint-lithography, in some instances, the resist layer 208 is patterned using nanoimprint lithography. For example, in some implementations, a mold with a desired pattern is brought into physical contact with the resist layer 208 on the curved surface 206 of the substrate 202. The mold may be formed of a flexible material, such as a UV curable polymer or thermal plastic, and may have the ability to stretch and to be deformed and recover to its originally shape after deformation. For example, the mold may be formed of silicone rubber, polyurethane elastomers, or natural rubber, or any other suitable elastomeric material. Pressure may be applied to the mold and resist layer 208 so as to transfer the mold pattern to the resist layer 208. The flexible mold is deformed under pressure to allow the mold to conform to the shape of the curved surface 206 to ensure good contact between the mold and the surface 206 substrate which leads to accurate replication of the desired pattern. Applying the mold to the resist layer 208 may result in the formation of regions where the resist layer 208 is thinned and other regions where the resist layer 208 is thicker. The mold may include a pattern that is complimentary to the pattern of metastructures desired to be formed on the curved surface 206. For instance, the mold pattern may include a pattern of repeating structures, such as a one-dimensional line grating or a two-dimensional line grating. The mold pattern may include square, rectangular, trapezoid, rhombus, star, diamond, arrowhead, or horseshoe patterns.

The resist layer 208 then is cured. In some cases, where the resist layer 208 is formed of a UV-curable resist, the mold and the substrate 202 are exposed to UV light for a period of time sufficient to cure the resist. In other cases, where the resist layer 208 is formed of a thermally curable resist, the mold and the substrate 202 are exposed to heat to cure the resist. After the resist is cured, the mold is separated from the substrate 202 to expose a patterned layer of resist 210 on the substrate 202. In some implementations, when a high refractive index nanoimprint resist with a refractive index ranging from 1.6-2.0 is used, the patterned resist 210 on the curved surface 206 may be the final device or may be processed further. For instance, the patterned resist 210 may include a distributed array of meta-atoms forming a one or two-dimensional grating on the curved surface 206. Alternatively, or in addition, the patterned resist 210 may include one or more lens elements.

An advantage of using imprint lithography on a curved surface with a flexible mold, as opposed to UV lithography or other pattern transfer techniques is that the flexible mold can be conformal to the curved surface 206, allowing the pattern to be reproduced accurately on the curved surface 206. In contrast, when using other lithography techniques such as UV exposure of resist through a mask, the pattern transferred to the resist may be skewed, potentially misaligned, and/or not conformal to the substrate surface, which in turn may adversely affect the shape and performance of the device being fabricated.

Next, as illustrated in FIG. 2D, residual resist is removed. Residual resist may include, for example, resist located between the structures imprinted in the resist. For instance, in FIG. 2D, the regions between protrusions 211 formed by imprinting may include residual resist that should be removed to expose the substrate before the next step in fabrication. Alternatively, or in addition, residual resist may include thin resist layers that surround the patterned region. The residual resist may be removed using non-directional or isotropic etching techniques, such as dry etching techniques including, e.g., plasma etching. Other suitable non-directional etching techniques may be used in some implementations. In some implementations, when a high refractive index nanoimprint resist with a refractive index ranging from 1.6-2.0 is used, after the residual resist is removed from the patterned resist 210 on the curved surface 206, as shown in FIG. 2D, may be the final device or may be processed further.

As illustrated in FIG. 2E, a first layer 212 then is deposited over the patterned resist 210. In some cases, the first layer 212 may be deposited by atomic layer deposition (ALD). For example, in some instances, the first layer 212 may include an oxide material with a high refractive index. In some cases, the first layer 212 may include titanium dioxide, amorphous silicon, niobium oxide (pentoxide), aluminum oxide, hafnium oxide, silicon oxide, strontium titanate oxide, tantalum oxide, gadolinium oxide, zirconium oxide, gallium oxide, vanadium oxide, among other materials. In some implementations, the first layer 212 may include a metal. Advantages of using ALD to deposit the first layer 212 may include, e.g., application of a conformal coating on the three-dimensional structures of the patterned resist layer 210, including high aspect-ratio geometries, geometries with sharp edges, precise film thickness control, and high quality films. In particular, using imprint lithography in conjunction with ALD may, in some implementations, allow formation of relatively complex geometries, including geometries such as, but not limited to, shapes with the following cross-sections: squares, rectangles, trapezoids, rhombuses, stars, diamonds, arrowheads, horseshoes, as well as geometries used in polarization dependent devices. In some implementations, the thickness of the deposited material fills the regions between protrusions in the patterned resist layer 210 such that a thickness of the deposited material in those regions is greater than a thickness of adjacent protrusions in the patterned resist layer 210. Although a single layer 212 of material is shown as formed on the patterned resist layer 210 in FIG. 2E, multiple layers of material may be formed on the patterned resist layer 210. The multiple layers may include the same material or may include a combination of different materials. For instance, in some implementations, the multiple layers may include a stack alternating between a first material and a second material. The first material and second material may have different refractive indices, e.g., alternating between materials with a high and low refractive index.

Next, as illustrated in FIG. 2F, an optional etch back of the first layer 212 is performed. In some cases, a portion of the first layer 212 may be etched back using a wet or dry etching technique. When the first layer 212 is etched back, material deposited on the surface of protrusions in the patterned resist layer 210 can be removed so as to expose portions of the underlying patterned resist layer 210.

Following the optional etch back, the patterned resist layer 210 is removed, as illustrated in FIG. 2G, leaving the patterned first layer 214 on the curved surface. The patterned resist layer 210 may be removed using a wet etching technique using solvents and/or oxidizing chemistries or using a dry etching technique, such as plasma techniques or reactive ion etching. The patterned layer 214 formed on the curved surface 206 may include one or more metastructures, as described herein. For instance, the metastructures may include nanostructures such as columns, pillars, lines, or other shapes. Due to the conformal nature of the imprint lithography and ALD process in forming the metastructures, the metastructures may be formed such that the height of each structure extends normal to the surface of the curved substrate on which they are positioned. In some implementations, when the patterned resist 210 is removed, the resulting structure, as shown in FIG. 2G, may be the final device or may be processed further.

Next, as illustrated in 2H an optional encapsulation material 216 is formed over the patterned layer 214 to encapsulate the one or more metastructures formed on the curved surface 206. In some cases, the encapsulation material 216 is a spin-on glass material or polymer. In some cases, the polymer may include a photoresist material that is spun on and then cured may act as encapsulation material. The encapsulation material 216 may act as a protective layer which can help to protect the metastructures from physical, chemical and/or environmental degradation. In some cases, the thickness of the encapsulation material 216 is at least the thickness of the structures formed in the patterned layer 214. In some cases, the thickness of the encapsulation material 216 is at least two times the wavelength of light for applications in which the metastructure is to be used. In some cases, the encapsulation material 216 may be a material with a refractive index of 1.2-2.1. In some implementations, when the encapsulation material 216 is formed over the patterned layer 214, the resulting structure shown in FIG. 2H may be the final device or may be processed further.

In some implementations, as illustrated in FIG. 2I, an optional reflective or anti-reflective coating 218 is formed. The reflective or anti-reflective coating 218 may be formed on a surface of encapsulation material 216 or, if no encapsulation material is present, on a surface of one or more of the metastructures of the patterned layer 214. The coating 218 may be formed using, e.g., physical vapor deposition techniques such as thermal evaporation, e-beam evaporation, or sputtering, among others. In some implementations, the coating 218 may be formed using ALD. In some implementations, the coating 218 may be formed on the backside surface of the substrate 202.

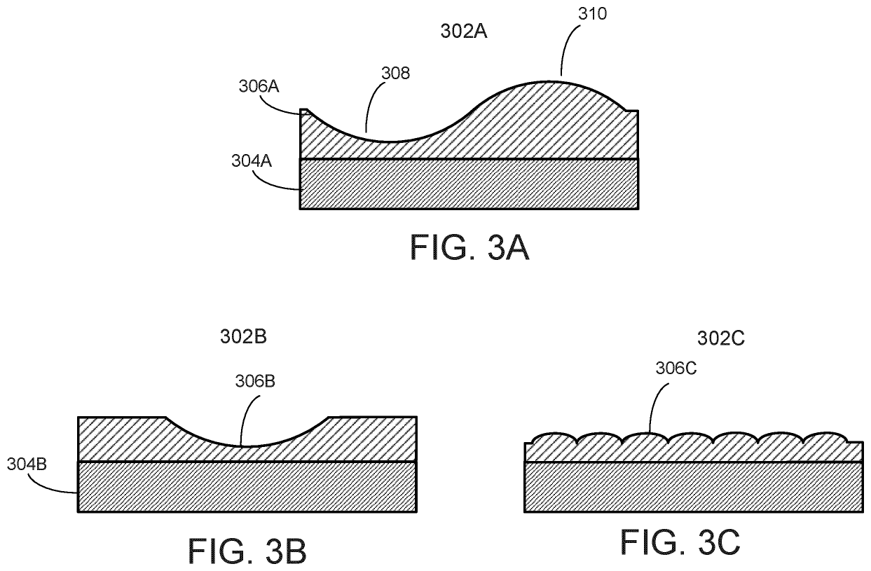

As explained herein, the curved surface 206 is not limited to surfaces that are convex with respect to the substrate 204. FIGS. 3A-3C illustrate examples of different types of substrates with curved surfaces. FIG. 3A depicts a substrate 302A having a surface that is both convex and concave with respect to the substrate 304A. FIG. 3B depicts a substrate 302B having a surface 306B that is concave with respect to the substrate 304B. FIG. 3C depicts a substrate 304C that includes multiple lenses arranged in an array. As explained herein, a substrate may be understood to include a support layer in which the curved surfaces are formed.

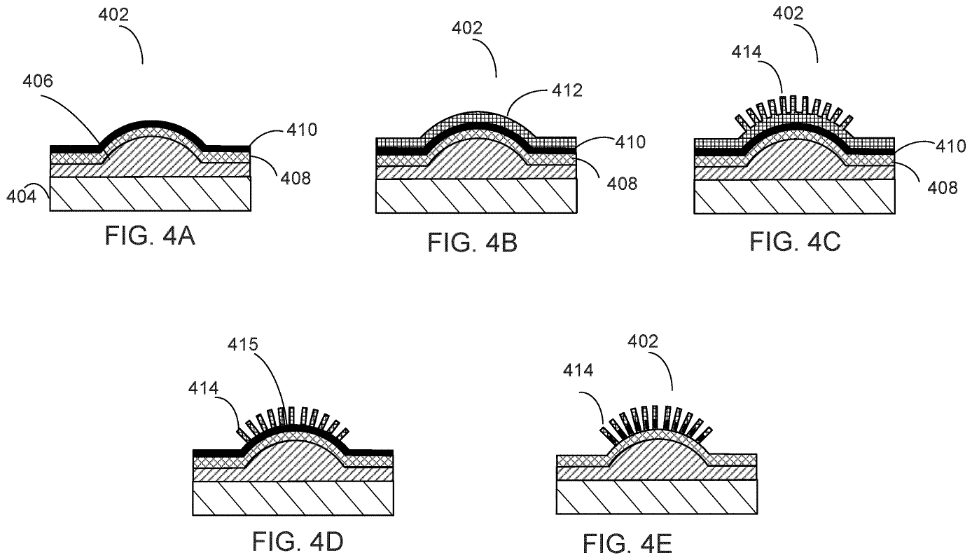

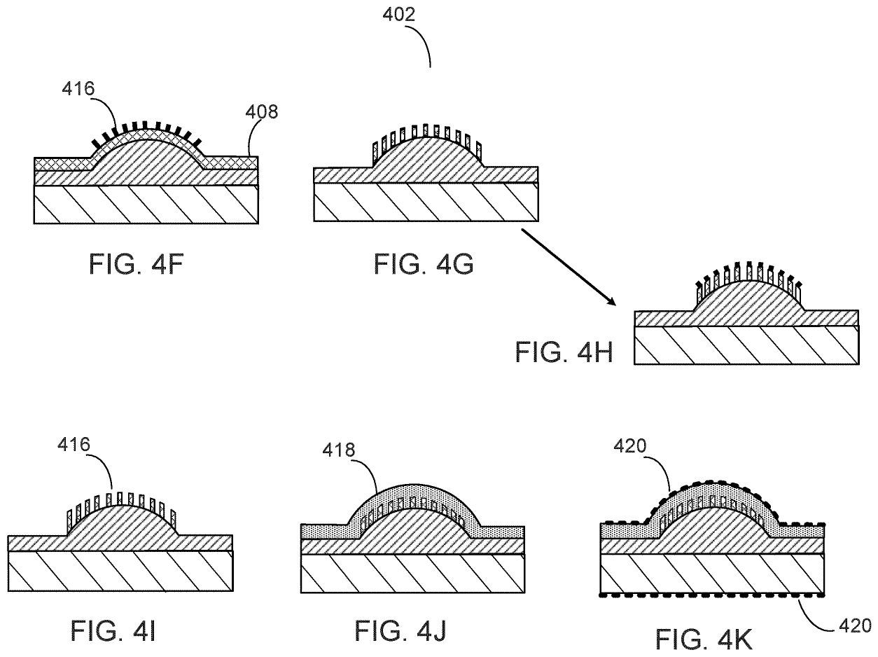

FIGS. 4A-4K illustrate manufacturing steps for forming a device that includes one or more metastructures on a curved surface that includes a high index refractive medium layer. Utilizing a high index refractive medium layer provides an advantage of enabling the fabrication of metastructures with higher transmission and enabling to bend light for a larger range of angles. When used in fabricating optical devices, the high index refractive medium help to improve the performance of the optical devices by increasing the optical efficiency. The fabrication process described with respect to FIGS. 4A-4K utilizes a subtractive process to create the patten on the curved surface. The subtractive process leads to the formation of metastructures which are precisely formed, well defined, and have a high resolution.

As illustrated in FIG. 4A, a substrate 402 is provided. The substrate 402 may include a curved surface 406. Although shown as convex with respect to the substrate 402, the curved surface 406 may alternatively be concave include a combination of convex and concave features. The substrate 402 may include a support layer 404 in which the curved surface 406 is formed. The material of substrate 402 and/or support layer 404 may be selected to be optically transmissive with respect to a particular wavelength or range of wavelengths of radiation (e.g., infra-red (IR), near-infrared (NIR), short-wave infrared (SWIR), visible light) depending on the application(s) in which the device is to be used.

As shown in FIG. 4A, a high refractive index material layer 408 may be provided on the substrate 402, e.g., on top of the curved surface 406. In some implementations, the high refractive index layer 408 is provided directly on the substrate surface, such as directly on the support layer 404. The high refractive index layer 408 may include material such as amorphous silicon, titanium dioxide, tantalum pentoxide, niobium oxide (pentoxide), aluminum oxide, hafnium oxide, silicon oxide, strontium titanate oxide, tantalum oxide, gadolinium oxide, zirconium oxide, gallium oxide, vanadium oxide, or silicon nitride. The layer 408 of the high refractive index material may be formed using different deposition techniques, such as physical vapor deposition (e.g., thermal evaporation or sputtering), e-beam deposition, among other processes.

In some implementations, a hard mask layer 410 is provided over the high refractive index layer 408. The hard mask layer 410 may be used later in processing to transfer a pattern to the underlying high refractive index layer 408. The hard mask layer 410 may include a metal, such as, but not limited to, chrome, aluminum, or titanium. In some implementations, the hard mask layer 410 may include tungsten, titanium nitride, silicon nitride, or silicon dioxide. In some implementations, the hard mask layer 410 may be a composite hard mask, composed of multiple layers of different materials. The hard mask 410 may be formed using different deposition techniques, such as chemical vapor deposition, atomic layer deposition, physical vapor deposition (e.g., thermal evaporation or sputtering), e-beam deposition, among other processes.

Next, as shown in FIG. 4B, at least one resist layer 412 is formed on the hard mask 410. In some cases, the at least one resist layer 412 includes a nanoimprint resist that is a UV-curable resist. In other examples, the at least one resist layer 412 includes a thermally curable resist. The resist layer 412 may be applied by different deposition techniques. For example, in some cases, the resist layer 412 is applied by spin-on processes, spray coating processes, or injection dispensing processes.

As show in FIG. 4C, the resist layer 412 on the curved surface 406 is patterned using imprint-lithography techniques. As described above with reference to FIG. 2, for example, a mold with a desired pattern is brought into physical contact with the resist layer 412. The mold may be formed of a flexible material, such as a UV curable polymer or thermal plastic, and may have the ability to stretch and to be deformed and recover to its originally shape after deformation. For example, the mold may be formed of silicone rubber, polyurethane elastomers, or natural rubber, or any other suitable elastomeric material. Pressure may be applied to the mold and resist layer 412 so as to transfer the mold pattern to the resist layer 412. The flexible mold is deformed under pressure to allow the mold to conform to the shape of the curved surface 406 to ensure good contact between the mold and the surface 406 substrate which leads to accurate replication of the desired pattern. Applying the mold to the resist layer 412 may result in the formation of regions where the resist layer 412 is thinned and other regions where the resist layer 412 is thicker. The mold may include a pattern that is complimentary to the pattern of metastructures desired to be formed on the curved surface 406. For instance, the mold pattern may include a pattern of repeating structures, such as a one-dimensional line grating or a two-dimensional line grating. The mold pattern may include concentric circles or other patterns, such as, square, rectangular, trapezoid, rhombus, star, diamond, arrowhead, or horseshoe patterns.

The resist layer 412 then is cured. In some cases, where the resist layer 412 is formed of a UV-curable resist, the mold and the substrate 402 are exposed to UV light for a period of time sufficient to cure the resist. In other cases, where the resist layer 412 is formed of a thermally curable resist, the mold and the substrate 402 are exposed to heat to cure the resist. After the resist is cured, the mold is separated from the substrate 402 to expose a patterned layer of resist 414 on the substrate 402.

Next, as shown in FIG. 4D, any residual resist is removed. Residual resist may include, for example, resist located between the structures imprinted in the resist. The residual resist may be removed using non-directional or isotropic etching techniques, such as dry etching techniques including, e.g., plasma etching. Other suitable non-directional etching techniques may be used in some implementations.

Removing residual resist may result in portions 415 of the hard mask 410 being exposed. As illustrated in FIG. 4E, the exposed portions of the hard mask 410 are removed. By removing the exposed portions of the hard mask 410, the pattern from resist layer 412 is transferred to the underlying hard mask layer 410, and portions of the high refractive index layer 408 are then exposed. The portions of the hard mask 410 may be removed using wet or dry etching processes that do not remove or minimally remove the high refractive index layer. Preferably, in some implementations, the exposed portions of the hard mask 410 are removed using anisotropic etching so that patterned resist features are not undercut.

As illustrated in FIG. 4F, the remaining portion of patterned resist layer 414 is removed, leaving the patterned mask layer 416 on the high refractive index layer 408. The patterned resist layer 412 may be removed using a wet or dry etching that does not remove or minimally removes exposed portions of the underlying high refractive index layer 408.

As illustrated in FIG. 4G, when a thin hard mask 410 is used, portions of the high refractive index layer 408 that are exposed are removed, whereas portions of the high refractive index layer 408 under the hard mask 410 are protected from removal and remain on the curved surface. In some implementations, the thin hard mask 410 may have a thickness of 5-20 nanometers. The portions of the high refractive index layer 408 may be removed using a directional etching technique, such as reactive ion etching, inductively coupled plasma etching, or deep reactive ion etching. Other suitable directional etching techniques may be used in some implementations. In some cases, a thick hard mask 410 is used, as illustrated in FIG. 4H, the directional etching of the high refractive index material 408 may cause a shadowing effect where some areas have reduced exposure or complete shadowing. In some implementations, the thick hard mask 410 may have a thickness of 20-200 nanometers.

As illustrated in FIG. 4I, the remaining hard mask 410 portions are removed by etching techniques. In some cases, the hard mask portions 410 may be removed using a wet etching technique. In other cases, the hard mask fragments 410 may be removed using a dry etching technique. Other suitable etching techniques may be used in some implementations. When the hard mask portions 410 are removed by etching, the patterned layer 414 is formed on the curved surface 406, and may include a plurality of meta-optical structures 416. Each of the plurality of meta structures 416 have a cross sectional width of 30-500 nanometers. In some examples, when the plurality of metastructures are formed in a circular or cylindrical shape, the diameter of each structure is 30-500 nanometers. In some implementations, the plurality of metastructures may have a diameter of up to 1000 nanometers. The patterned layer 414 may be formed in a pattern that is complimentary to the mold used to pattern the resist layer 412. In some implementations, when the hard mask 410 is removed, the resulting structure shown in FIG. 4I, may be the final device or may be processed further.

Next, as illustrated in FIG. 4J, an optional encapsulation material 418 is formed over the patterned layer 416 to encapsulate the one or more metastructures formed on the curved surface 406. In some cases, the encapsulation material 418 is a spin-on glass material or polymer. In some cases, the polymer may include a photoresist material that is spun on and then cured may act as encapsulation material. The encapsulation material 418 may act as a protective layer which can help to protect the metastructures from physical, chemical and/or environmental degradation. In some cases, the thickness of the encapsulation material 418 is at least the thickness of the structures formed in the patterned layer 416. In some cases, the thickness of the encapsulation material 418 is at least two times the wavelength of light for applications in which the metastructure is to be used. In some cases, the encapsulation material 418 has a refractive index of 1.2-2.1. In some implementations, when the encapsulation material 418 is formed over the patterned layer 416, the resulting structure, as shown in FIG. 4J may be the final device or may be processed further.

Then, as illustrated in FIG. 4K, an optional reflective or anti-reflective coating 420 is formed. The reflective or anti-reflective coating 420 may be formed on a surface of encapsulation material 418 or, if no encapsulation material is present, on a surface of one or more of the metastructures of the patterned layer 416. The coating 420 may be formed using, e.g., physical vapor deposition techniques such as thermal evaporation, e-beam evaporation, or sputtering, among others. In some implementations, the coating 420 may be formed using ALD. In some implementations, the coating 420 may be formed on the backside surface of the substrate 402.

A number of implementations of the invention have been described. Nevertheless, it will be understood that various modifications may be made without departing from the spirit and scope of the invention. Accordingly, other implementations are within the scope of the following claims.

1. A method comprising:
providing a substrate comprising a curved surface;
forming a resist layer on the curved surface;
patterning the resist layer on the curved surface using imprint lithography to provide a patterned resist layer;
removing residual resist material from the patterned resist layer;
forming, by atomic layer deposition, a first layer on the patterned resist layer; and
removing the patterned resist layer to form a patterned first layer on the curved surface.

2. The method of claim 1, wherein the patterned first layer on the curved surface comprises a metastructure.

3. The method of claim 2, wherein the metastructure includes one or more structures formed perpendicular to the curved surface, and a height of each of the one or more structures is formed to be normal to the curved surface.

4. The method of claim 3, wherein each of the one or more structures formed perpendicular to the curved surface have a diameter of 30-500 nanometers.

5. The method of claim 1, further comprising:
encapsulating the patterned first layer in an encapsulation material.

6. The method of claim 5, wherein the encapsulation material comprises spin-on glass or polymer.

7. The method of claim 1, comprising removing a portion of the first layer so as to expose at least part of the patterned resist layer.

8. The method of claim 7, wherein removing the portion of the first layer so as to expose at least a part of the patterned resist layer comprises performing an etch of the first layer.

9. The method of claim 1 wherein the substrate is a substrate that is transparent to visible light, infrared, near-infrared, or short-wave infrared.

10. The method of claim 1, wherein patterning the resist layer comprises:
physically contacting a mold to the resist layer, wherein the mold comprises a pattern;
pressing the mold and the substrate together;
curing the resist; and
separating the mold from the resist layer to form the patterned resist layer.

11. The method of claim 10, wherein the mold comprises a flexible material.

12. The method of claim 1, wherein the curved surface comprises a convex surface with respect to the substrate.

13. The method of claim 1, wherein the curved surface comprises a concave surface with respect to the substrate.

14. The method of claim 1, wherein the curved surface comprises a combination of multiple convex surfaces with respect to the substrate.

15. The method of claim 1, wherein the curved surface comprises a combination of multiple concave surfaces with respect to the substrate.

16. The method of claim 1, wherein the curved surface comprises a concave surface with respect to the substrate and a convex surface with respect to the substrate.

17. The method of claim 1, wherein the resist is a thermally curable or UV-curable resist.

18. The method of claim 1, wherein removing the residual resist material comprises using a dry etching technique.

19. The method of claim 1, wherein the first layer comprises amorphous silicon, niobium oxide, titanium oxide, aluminum oxide, hafnium oxide, silicon oxide, strontium titanate oxide, tantalum oxide, gadolinium oxide, zirconium oxide, gallium oxide, or vanadium oxide.

20. A device comprising:
a substrate comprising a curved surface; and
one or more metastructures on the curved surface.

21. The device of claim 20, wherein the one or more metastructures o the curved surface has a diameter of up to 1000 nanometers.
